(19) United States
(12) Patent Application Publication
(10) Pub. No.: US 2006/0033187 A1
(43) Pub. Date: Feb. 16, 2006

(54) Rugged CSP module system and method

(75) Inventors: James Wilder, Austin, TX (US); James Douglas Wehrly JR., Austin, TX (US)

Correspondence Address: J. SCOTT DENKO, ANDREWS & KURTH LLP, 111 CONGRESS AVE., SUITE 1700, AUSTIN, TX, 78701, US

(73) Assignee: Staktek Group, L.P.

(21) Appl. No.: 10/917,216

(22) Filed: Aug. 12, 2004

(51) Int. Cl. H01L 23/495

(52) U.S. Cl. 257/668

(57) ABSTRACT

A rugged CSP module system and method are disclosed. In one embodiment of the present invention, a unitary mount is attached to a chip scale integrated circuit (CSP) to provide a CSP module with improved temperature cycle performance. In an exemplary system, the mount comprises a two metal layer flexible circuit attached to the CSP. Contacts are distributed along the flexible circuit for attachment to a printed circuit board (PCB). The body of the CSP then stands off from the PCB by the sum of the heights of the CSP contacts, the flex circuit, and the diameter of the contacts distributed along the flex circuit. Consequently, the forces arising from mismatched temperature coefficients of the PCB and CSP are distributed along a longer axis thus improving temperature cycle performance.

### TECHNICAL FIELD

The present invention relates to integrated circuit packaging and, in particular, to a system and method for mitigation of thermally-induced stress in chip-scale package applications.

### BACKGROUND OF THE INVENTION

In use, integrated circuit packages (IC packages) are exposed to a variety of environmental stresses. For example, high ambient temperatures can contribute to heat accumulation in the IC package and consequent shorter life or less reliability. Impact shock can affect internal connections or plastic package integrity. Changes in ambient temperature can cause mechanical stress that may break connections between the IC package and the circuit board upon which the IC is mounted.

Consequently, system designers have devised test protocols intended to eliminate less reliable proposed component designs. Such test protocols are intended to mimic, in an enhanced and typically accelerated form, the stresses that the proposed component would experience in use.

The widening use of ICs in more ubiquitous and numerous applications has increased the electronic and environmental performance demands on packaged integrated circuitry. Even so, the simultaneous trend of rising complexity has made reliability more difficult to achieve.

Temperature variation precipitates material expansion or contraction. All materials do not expand or contract at the same rates when exposed to the same temperature gradient. Thermally induced expansion or contraction in a material is quantified by an attribute known as the coefficient of thermal expansion or CTE. Consequently, when physically connected dissimilar materials expand or contract differently or, have different CTE's, mechanical stresses are induced between the dissimilar materials.

It is well known that IC packages typically have CTE's that differ from the CTE of the board upon which such IC packages are typically mounted. Package durability and package-board connection integrity under rapid temperature variation is one attribute that that is closely scrutinized in evaluating proposed component package designs. In traditional surface mount devices such as quad flat packages or thin small outline packages (TSOPs) the leads and solder joints provide the compliance needed to absorb the mismatch between the package and the board upon which the package is mounted.

In area array devices however, the small joint between the package and the board must absorb the bulk of the stresses arising from the mismatched CTE's between board and package. This is particularly true as circuit complexity increases and such packages exhibit smaller and smaller contacts. Chip scale packages typically exhibit an increased number of contacts as circuit complexity increases. However, the major package surface area across which the increased number of contacts is distributed tends to stay about the same if not diminish. Thus contact density increases and individual contact size decreases. With smaller contact diameters, the distance from the CSP body to the mounting circuit board typically decreases and the physical demands on the contacts increases while their quality becomes critical. In a board-CSP connection, it is the contacts that realize not only the electrical connection, but the physical connection as well and thus the connections provide the bulk of the coefficient of thermal expansion mismatch compliance. Consequently, higher complexity CSPs with smaller contacts may not exhibit sufficient reliability for high demand applications when exposed to rapid temperature variation or “temperature cycling”, as this characteristic is commonly called.

What is needed, therefore, is a technique and system for individual integrated circuit packages packaged in chip scale technology that provides a thermally-efficient, reliable system that performs well at higher frequencies, does not add excessive height to the device and allows production at reasonable cost with readily understood and managed materials and methods but exhibits enhanced performance under temperature variation regimes.

### BACKGROUND OF THE INVENTION

The present invention attaches a mount to a CSP to provide a CSP module with improved temperature cycle performance. The present invention can be used to advantage with CSP packages of a variety of sizes and configurations where an array of contacts is distributed on a major package surface. Although in a preferred mode, the present invention will be applied most frequently to chip scale packages that contain one die it may be employed with chip scale packages that include more than one integrated circuit die in any of several configurations whether flip-chip or chip-on-board (COB) or board-on-chip (BOC).

In a module devised in accordance with a preferred embodiment of the present invention, a flexible circuit is attached to a CSP that is comprised of a die attached to a substrate. The flexible circuit exhibits one or more and preferably two metal layers while providing not only an increased stand off dimension but compliance flexibility between the CSP and the board upon which the CSP is mounted. One major side of the flex circuitry is attached to the CSP while the other major side of the flex circuitry exhibits contacts for attachment of the module to a circuit board. The substrate body of the CSP then stands off from the board by the sum of the heights of the CSP contacts, the flex circuitry and the diameter of the contacts distributed along the flex circuitry. Consequently, the forces arising from CTE mismatch between the circuit board and CSP are distributed along a longer axis thus improving temperature cycle performance.

### SUMMARY OF THE DRAWINGS

FIG. 1 is an elevation view of a prior art CSP mounted on a circuit board.

FIG. 2 is an elevation view of module 10 devised in accordance with a preferred embodiment of the present invention.

FIG. 3 is an elevation depiction of another prior art CSP mounted on a circuit board.

FIG. 4 is an elevation depiction of a module 10 devised in accordance with a preferred embodiment of the present invention.

FIG. 5 depicts, in enlarged view, the area marked “A” in FIG. 4.

FIG. 6 depicts an interposer employed in a preferred embodiment of the present invention;

FIG. 7 depicts an interposer employed in an alternative embodiment of the present invention;

FIG. 8A illustrates placement of a CSP on a printed circuit board;

FIG. 8B depicts an exemplary placement of a CSP on a printed circuit board in accordance with a preferred embodiment of the present invention; and

FIG. 9 represents an exemplary computer system in accordance with an embodiment of the present invention.

### DESCRIPTION OF PREFERRED EMBODIMENTS:

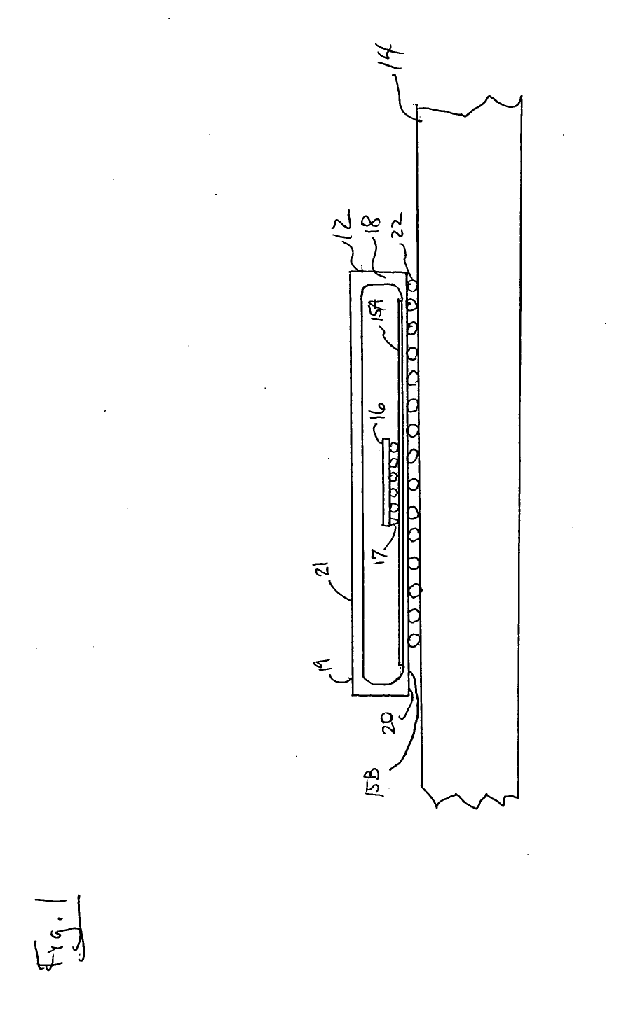

FIG. 1 is an elevation view of a CSP 12 mounted on a circuit board 14. For purpose of this disclosure, the term CSP is to be broadly construed to include all sizes of array contact IC packages, whether larger BGA's or smaller micro-BGA's and other array contact devices. CSPs include chip scale packages that include one or more integrated circuit die in any of several configurations whether flip-chip or chip-on-board (COB) or board-on-chip (BOC) on a substrate having an array of contacts on a major surface.

In FIG. 1, CSP 12 is shown in a cross-sectional depiction to illustrate IC 16 contained within casing 18. IC 16 is depicted as a die flip-chip with contact bumps 17 bonded to substrate 15, but IC 16 may be connected to the substrate in any of the several modes known in the art including but not limited to flip-chip, chip-on-board (COB) or board-on-chip (BOC). For purposes of understanding the invention, substrate 15A and the lower planar floor 15B of casing 18 should together be considered, for this example to be substrate 15 of the CSP.

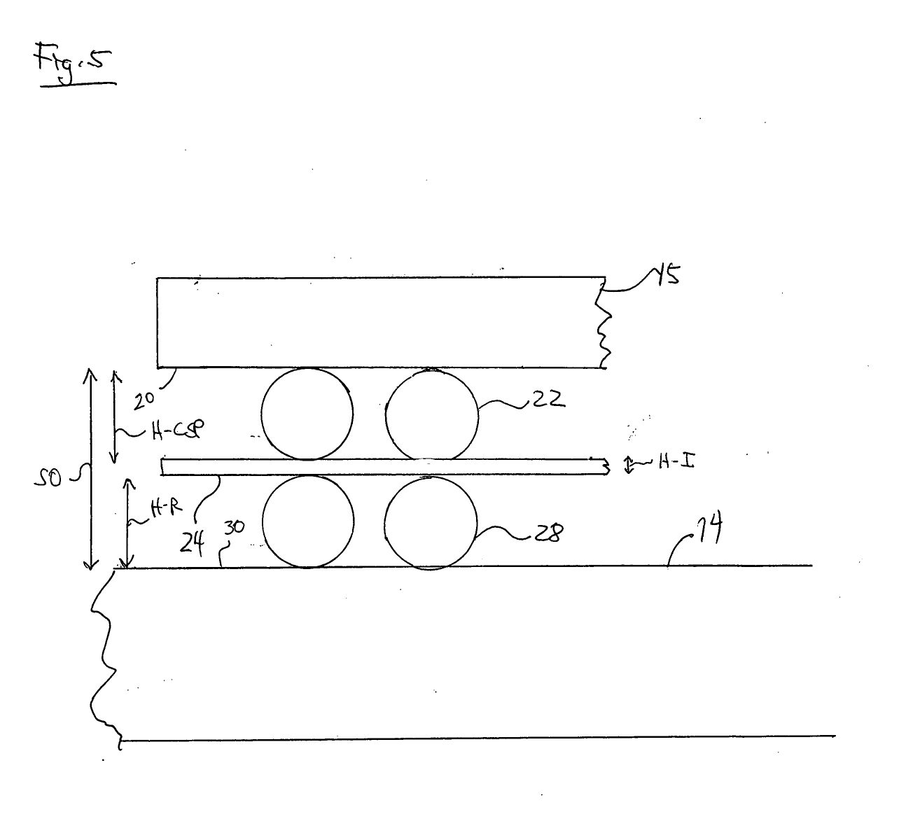

Casing 18 exhibits a lid 19 having upper major surface 21 and a lower major surface 20 along which are found CSP contacts 22 each having a height “H-CSP” as shown more clearly in later FIG. 5.

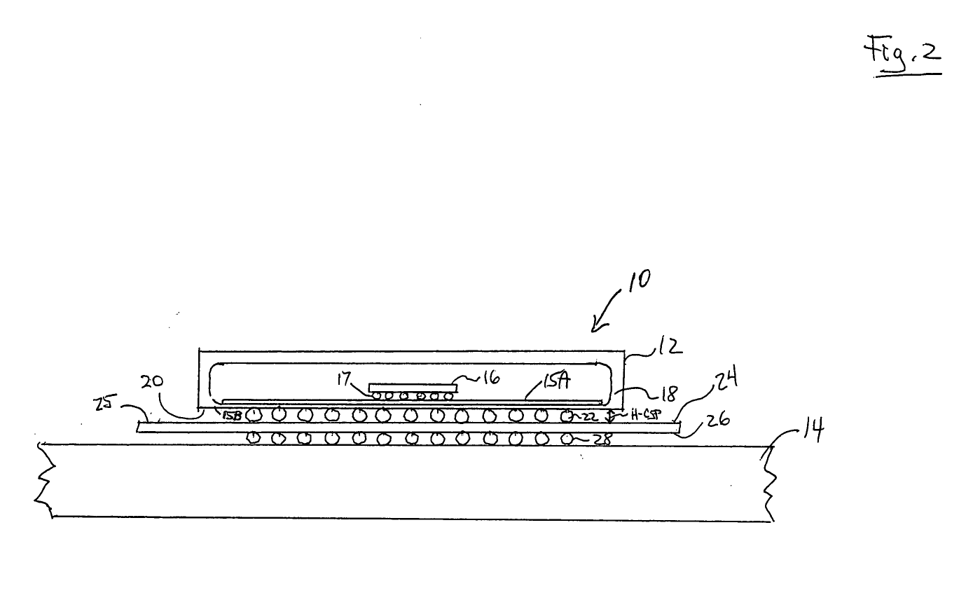

FIG. 2 depicts a rugged module 10 devised in accordance with a preferred embodiment of the present invention. In module 10, CSP 12 of FIG. 1 is attached to interposer mount 24. In a preferred embodiment, unitary mount 24 is comprised of a flexible circuit and has upper surface 25 and lower surface 26. Within the preferred modes implemented with a flexible circuit, a flexible circuit that exhibits flexibility across its extent, or a rigid-flex that is flexible in sectors and more rigid in other sectors either with or without defined enhanced relief areas may be used. However, other materials that provide stand off and, optionally, compliance attributes, may also be employed to advantage. The invention is best adapted when a mount of unitary structure (a unitary mount) is employed. There are known prior art interposer systems, but such systems do not employ unitary structures such as those disclosed here which, despite having one or multiple constituent layers, are attachable to a CSP as a single aggregate piece thus providing significant manufacturing and cost advantages. For example, a business may acquire CSPs and attach a flexible circuit having appropriate contact fields on each of its two major sides to the acquired CSPs and after contact population of the flex circuit, be able to efficiently provide CSP modules having improved thermal cycling performance without engaging in managing the structural and connective complexities of earlier systems and methods.

In a preferred embodiment, unitary mount 24 will be a flexible circuit that exhibits multiple layers to provide flexibility for high contact count devices and optional opportunities to mitigate ground bounce phenomena by, for example, balancing signal and ground in custom applications. An array of contacts 28 is distributed across the lower surface 26 of mount 24 to provide connective facility for attachment to circuit board 14. Typically, contacts 28 will be solder balls or other substantially spherical contacts most often comprised of solder.

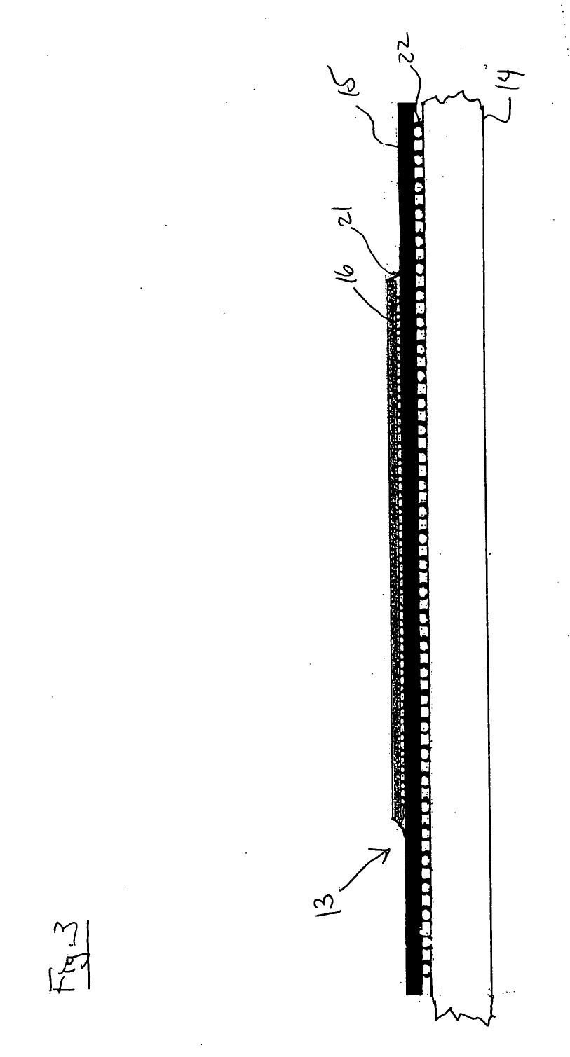

FIG. 3 depicts a prior art CSP device 13 comprised of a die 16 flip chip bonded to substrate 15. Optional underfill 21 is shown at the juncture of die 16 and substrate 15. CSP 13 is attached to board 14 through the array of contacts 22. FIGS. 1 and 3 are meant to depict only a couple of examples of the many types of CSPs that may be employed with the present invention. Additional, but non-limiting examples include, CSPs comprised of: a die flip chip bonded to a substrate, underfilled and overmolded with plastic, a die mounted face up and wire bonded to a substrate, and a die mounted face down and wire bonded to a substrate as well as the other variations of die and array contact populated substrates known to those in the art as array devices or, in this disclosure as CSPs.

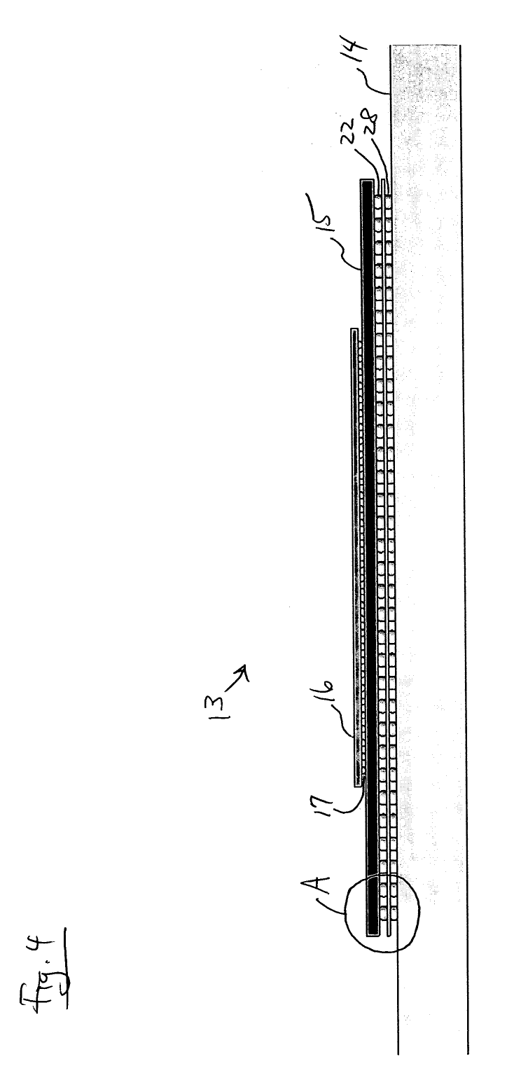

FIG. 4 is an elevation depiction of another module 10 devised in accordance with a preferred embodiment of the present invention. As shown in FIG. 4, CSP 13 is mounted on mount 24 which is populated with contacts 28 which are connected to circuit board 14. Consequently, both die 16 and substrate 15 are set off from board 14 by the thickness of CSP contacts 22, contacts 28 and mount 24.

FIG. 5 depicts in enlarged view, the area marked “A” in FIG. 4. As shown in FIG. 5, the distance or stand off (SO) from the lower major surface 20 of substrate 15 to the surface 30 of board 14 includes the height “H_{CSP}” of CSP contacts 22 plus the thickness “H_{I}” of mount 24 plus the height “H_{R}” of contacts 30.

In typical applications, board 14 is composed of what is known as FR4 laminate that is familiar to those of skill in the art. However, board 14 may be any circuit or other board upon which a CSP is mounted. The thermal expansion coefficient for typical FR4 is as follows in Table 1.

TABLE 1
Coefficient of Thermal Expansion

| | |
|---|---|
| x-axis | 14 ppm/° C. Ambient to the transition |
| | temperature (Tg) |
| y-axis | 13 ppm/° C. Ambient to the transition |
| | temperature (Tg) |
| z-axis | 175 ppm/° C. Ambient to 288° C. |

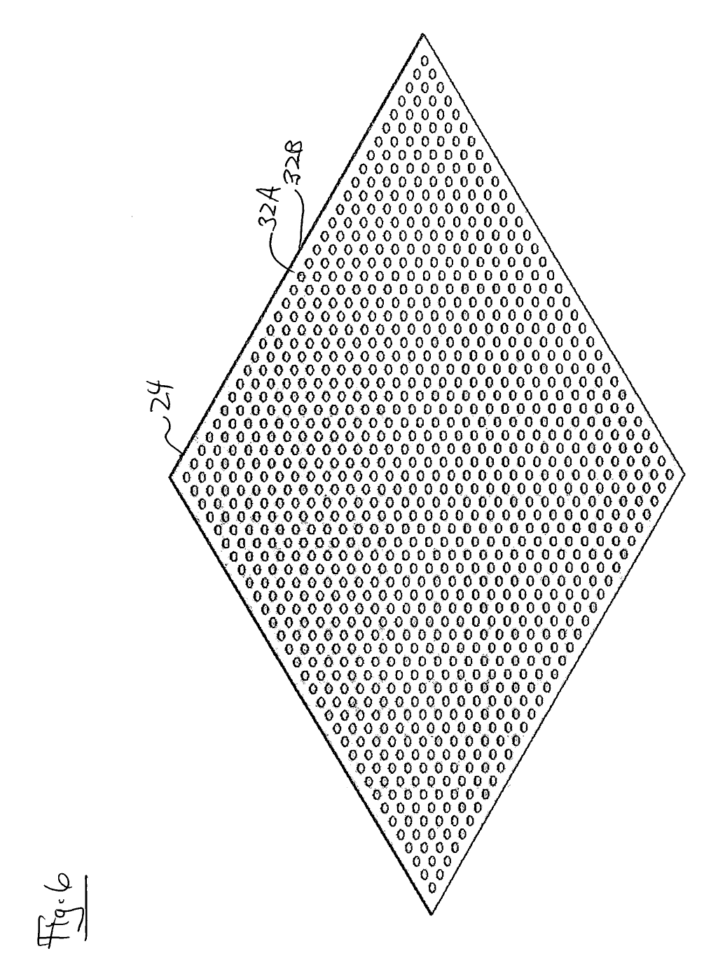

FIG. 6 depicts one type of mount 24 that may be employed in a preferred embodiment of the present invention. Depicted mount 24 is a two metal layer flex circuit of unitary structure having contact sites 32A and 32B on upper and lower major sides 25 and 26 respectively through which are conveyed signals and current between exemplar CSPs 12 or 13 and board 15.

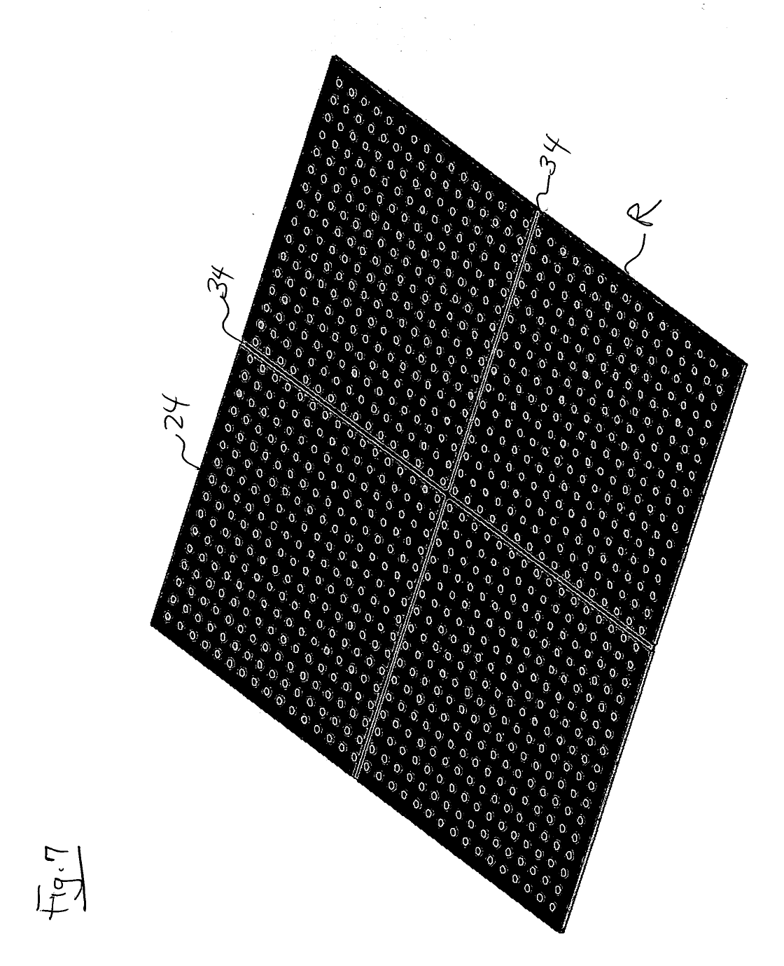

FIG. 7 depicts another substrate mount 24 as may be employed in a preferred embodiment of the present invention. Depicted substrate mount 24 is of unitary structure and exhibits expansion relief channels 34 that provide particular areas for dissipation of thermally induced expansive forces. The mount 24 shown in FIG. 7 may also be comprised of rigid sections R delineated from each other by relief channels 34 but interconnected with a flexible base such as polyimide.

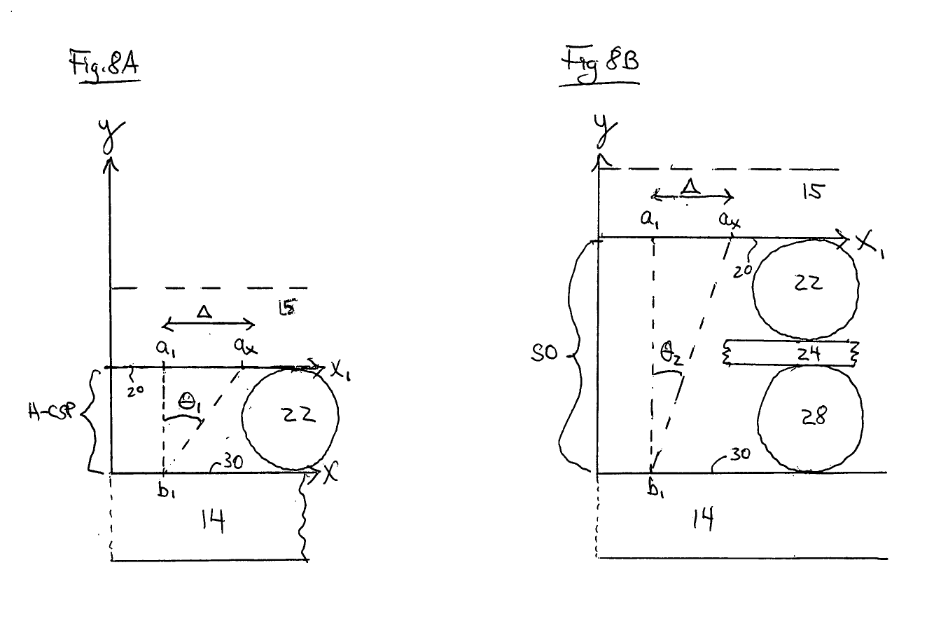

FIGS. 8A and 8B compare a first order heuristic illustration of relative deformative forces between substrate 15 and board 14 for the case of FIG. 3 (as illustrated in FIG. 8A) and in the case of module 10 shown in FIG. 4. FIG. 8A designates an arbitrary fixed point a₁ on lower surface 20 of substrate 15 for the CSP shown in FIG. 3 and a fixed point b₁ on upper surface 30 of board 14 with a₁ being directly above b₁. The illustration of FIG. 8A postulates relative movement of point a₁ to point aₓ relative to point b₁ on upper surface 30 of board 14 when the CSP of FIG. 3 is exposed to a thermal gradient of arbitrary characteristic. The degree of movement is delta (Δ). Those of skill will recognize that neither the absolute characteristic of the thermal gradient nor the absolute magnitudes of the distances illustrated are important to the exposition here offered to illustrate, in magnified form, thermally induced stresses when the stand off increases between board 14 and substrate 15. Therefore, point a₁ has moved relative to board 14 by Δ. Thus an imaginary angle θ₁ describes the degree of angular movement and may be considered a proxy for the amount of mechanical stress induced by the thermal gradient.

In FIG. 8B, the same thermal gradient is applied to the system shown in FIG. 4 and the relative displacement of a₁ is considered in light of the greater distance SO between substrate 15 and board 14. Thus, a₁ moves again to aₓ but the angle θ₂ now describes the relative displacement between board 14 and substrate 15. Angle θ₂ may be described by Equation 1:

$${θ}_{2} = {tan}^{- 1} ( \frac{Δ}{{H}_{CSP} + {H}_{I} + {H}_{R}} ) \qquad ( 1 )$$

where, Δ is the lateral movement of the substrate 15 with respect to the board 14, H_{CSP} is the height of the CSP contacts, H_{I} is the thickness of the interposer mount, and H_{R} is the height of contacts 30.

As is shown, angle θ₂ is less than angle θ₁ for the same degree of absolute displacement between substrate 15 and board 14. Thus, the displacement is less per unit of stand off. Those of skill will further note that this displacement is now distributed across the three structural features CSP contacts 22, mount 24 and contacts 28 rather than being concentrated in CSP contacts 22.

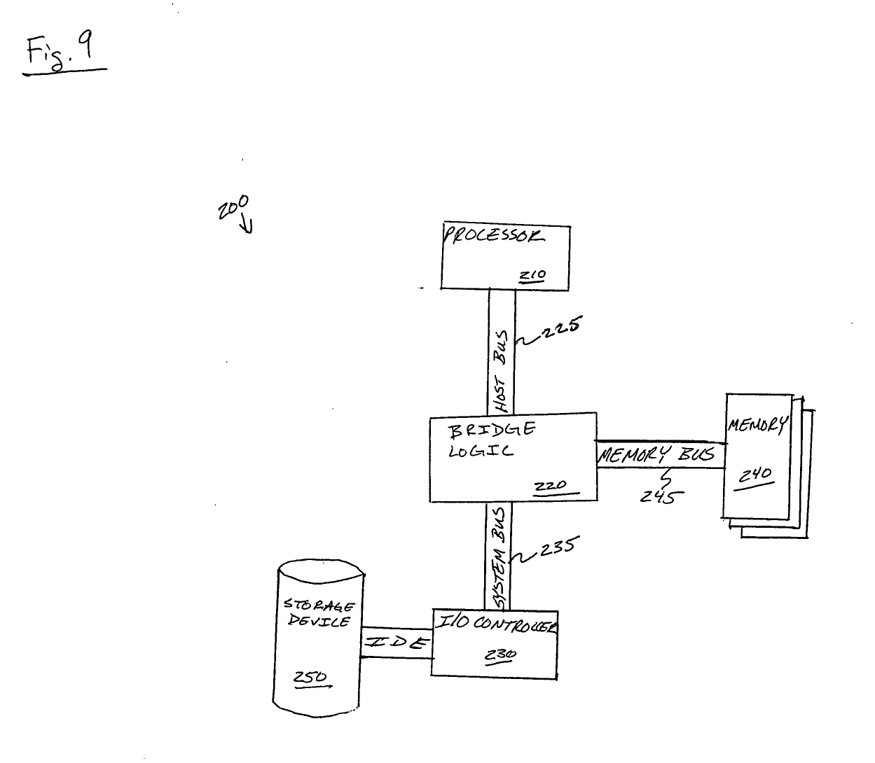

As can be appreciated by those of skill, embodiments of the present invention may be implemented in various electronic devices. FIG. 9 depicts a computer system 200 including a processor 210. Processor 210 is coupled to a bridge logic device 220 via a host bus 225. Host bus 225 preferably controls the flow of data between processor 210 and other devices in system 200. Bridge logic 220 further couples to an I/O controller 230 via system bus 235 and solid state memory 240 via memory bus 245. I/O controller 230 may include connections to various I/O devices. For example, storage device 250 may be an integrated drive electronics (IDE) type hard disk drive, and therefore its connection to I/O controller 230 is preferably via an IDE bus as shown. Memory 240 may be implemented using variety of ways, such as, solid state dynamic random access memory (DRAM) or static random access memory (SRAM). In general, the various devices in the computer system 200—i.e., processor 210, bridge logic 220, I/O controller 230, and memory bus 240—are packaged ICs. Accordingly, each of the devices in computer system 100 is capable of being mounted on a printed circuit board according to the methods disclosed herein.

Although the present invention has been described in detail, it will be apparent to those skilled in the art that the invention may be embodied in a variety of specific forms and that various changes, substitutions and alterations can be made without departing from the spirit and scope of the invention. The described embodiments are only illustrative and not restrictive and the scope of the invention is, therefore, indicated by the following claims.

1. A rugged circuit module comprising:
a single CSP comprising CSP contacts and one or more integrated circuit die mounted to a substrate; and
a planar unitary mount having first and second major sides and contact sites on each of said first and second major sides through which electrical signals are conveyable from the first major side to the second major side, the planar unitary mount being on its first major side, attached to the CSP contacts and, on its second major side, being populated with module contacts that correspond to the CSP contacts.

2. The circuit module of claim 1 in which the planar unitary mount is a flexible circuit having one or more metal layers.

3. The circuit module of claim 1 in which in the single CSP, the one or more integrated circuit die are mounted to the substrate in a flip-chip orientation.

4. The circuit module of claim 1 in which in the single CSP, the one or more integrated circuit die are mounted to the substrate face-up.

5. The circuit module of claim 1 in which in the single CSP, the one or more integrated circuit die are mounted to the substrate face-down.

6. The module of claim 1 attached to a circuit board with at least the module contacts.

7. The module of claim 6 in which only the CSP contacts, the planar unitary mount and the module contacts provide a stand off between the substrate and the circuit board.

8. An electrical assembly, comprising:
a printed circuit board (PCB);
an integrated circuit (IC) including a first array of contacts, wherein the IC is disposed adjacent to the PCB and lateral movement of the IC with respect to the PCB is measured as an angular shift; and
an interposer disposed between the PCB and the IC, wherein the interposer comprises a upper surface and a lower surface, the upper surface coupled to the first array of contacts, the lower surface coupled to a second array of contacts;
wherein the second array of contacts further couple to the PCB, thereby electrically coupling the PCB to the IC;
wherein a thermally-induced relative angular shift between the PCB and the IC is controlled by varying the cumulative height of a combination of the first and second arrays of contacts and the interposer.

9. The assembly of claim 8 in which interposer is unitary in structure.

10. The electrical assembly of claim 8, wherein the IC is a single chip scale package (CSP).

11. The electrical assembly of claim 8, wherein the interposer is a flex circuit.

12. The electrical assembly of claim 8, wherein the interposer includes a plurality of conductive layers that are electrically balanced.

13. An electrical assembly, comprising:
a plurality of chip scale packages (CSPs) disposed on a PCB;
a unitary interposer disposed between the plurality of CSPs and the PCB, the interposer comprising:
a rigid portion located substantially beneath each CSP within the plurality of CSPs; and
a flexible portion located substantially beneath gaps between the plurality of CSPs, wherein the flexible portion maintains electrical connection between the plurality of CSPs despite lateral shifting between the CSPs and PCB.

14. The electrical assembly of claim 13, wherein the rigid portion of the unitary interposer further comprises an upper surface and a lower surface, wherein the upper surface is coupled to an array of contacts located on a corresponding CSP, and wherein the lower surface is coupled to an array of contacts on the PCB.

15. The electrical assembly of claim 14, wherein the lateral shifting between the CSPs and the PCB is distributed across the combination of the unitary interposer, the array of contacts located on the CSP, and the array of contacts located on the PCB.

16. A method of reducing the lateral shifting between the CSPs and the PCB comprising the step of increasing the thickness of the unitary interposer.

17. The electrical assembly of claim 13, wherein the plurality of CSPs comprises a single layer of CSPs.

18. A method of manufacturing an electrical assembly, the method comprising the acts of:
providing a CSP including a first plurality of contacts;
coupling a unitary interposer to the first plurality of contacts to create a CSP-interposer module; and
coupling the CSP-interposer module to a second plurality of contacts located on a PCB;
wherein angular shift between the packaged IC and the PCB due to thermal variations is controlled by varying the thickness of the combination of the first and second pluralities of contacts and the interposer.

19. The method of claim 18 in which the act of coupling the CSP-interposer module comprises a direct coupling.

20. The method of manufacturing the electrical assembly of claim 19, wherein the unitary interposer couples a single CSP to the PCB.

21. The method of manufacturing the electrical assembly of claim 18, wherein the unitary interposer further comprises a flex circuit including multiple layers.

22. The method of manufacturing the electrical assembly of claim 18, further comprising the act of configuring the multiple layers of the flex circuit to electrically balance connections between the IC and the PCB.

23. A computer system, comprising:
a processor;
a storage medium coupled to the processor;
an CSP coupled to the processor, wherein the CSP is disposed above a PCB, and wherein the CSP experiences an angular shift θ with respect to the PCB, the angular shift θ characterized by:
$$θ = {tan}^{- 1} ( \frac{Δ}{{H}_{CSP} + {H}_{I} + {H}_{R}} ) , whereby \qquad ( 2 )$$
Δ represents lateral shifting of the CSP with respect to the PCB, H_{CSP} represents the height of a first array of contacts, H_{I} represents the thickness of an interposer connected directly to the CSP and the PCB, and H_{R} represents the height of a second array of contacts.

24. A method of controlling the lateral shifting of the CSP with respect to the PCB, the method comprising the step of providing an interposer of unitary structure.

25. The computer system of claim 23, wherein the interposer comprises multiple layers and varying the number of layers varies the angular shift θ.

26. The computer system of claim 23, wherein the diameter of the contacts in the second array of contacts is increased to reduce the angular shift θ.

27. A method for reducing a thermally-induced relative angular shift between a CSP and a PCB, the means comprising the steps of:
providing a unitary interposer having a first and a second set of contacts accessible from first and second major sides of the unitary interposer;
disposing the unitary interposer directly between the CSP and the PCB; and
connecting the CSP to the first set of contacts and the PCB to the second set of contacts.

28. The method of claim 27 in which the unitary interposer comprises flexible circuitry.

29. The method claim 28 in which the flexible circuitry has two or more metal layers.
